(19) United States
(12) Patent Application Publication
(10) Pub. No.: US 2025/0054840 A1
(43) Pub. Date: Feb. 13, 2025

(54) POWER MODULE HAVING A LEAD FRAME THAT PROVIDES SUBSTRATE SUPPORT AND FORMS TERMINALS OF THE POWER MODULE

(71) Applicant: Infineon Technologies AG, Neubiberg (DE)

(72) Inventor: Andreas Grassmann, Sinzing (DE)

(21) Appl. No.: 18/446,075

(22) Filed: Aug. 8, 2023

(51) Int. Cl. H01L 23/495; H01L 23/538

(52) U.S. Cl. CPC H01L 23/49506; H01L 23/49537; H01L 23/49562; H01L 23/49575; H01L 23/5381

(57) ABSTRACT

A power module includes: a lead frame having a base region and leads; a plurality of substrates each having a first metallized side attached to the base region of the lead frame, a second metallized side opposite the first metallized side, and an insulating body that electrically isolates the first and second metallized sides from one another; at least one semiconductor die attached to the second metallized side of each substrate; and a mold compound encapsulating the semiconductor dies and part of the lead frame. The semiconductor dies are electrically interconnected within the power module to form part of a power electronics circuit. The base region of the lead frame is electrically isolated from the power electronics circuit by the insulating body of the substrates. The leads of the lead frame protrude from one or more side faces of the mold compound and form terminals of the power module.

### BACKGROUND

Molded power modules face several technical challenges, including high material and process costs. A major cost driver for molded power modules is high performance ceramics used for isolation and die (chip) attach processes. Also, insufficient heat spreading arises within molded power modules due to insufficient space between dies and sub-optimal heat spreading through the ceramic substrates. The ceramic substrates included in molded power modules are typically exposed at the module backside. The ceramic material is mechanically delicate and has a high CTE (coefficient of thermal expansion) mismatch when sintered or soldered to an aluminum or copper cooler, causing thermo-mechanical reliability issues. The mechanical tolerances of molded power modules add up such that the exposed surface of the ceramic substrates are poorly defined, causing mold flash and variable gaps to the cooler which have to be compensated by a thick interlayer material such as solder paste. Changes to the module functionality (e.g., power output, pin configuration, etc.) require changes to the design and production concept and drive major investment.

Hence, there is a need form an improved molded power module design.

### SUMMARY

According to an embodiment of a power module, the power module comprises: a lead frame having a base region and a plurality of leads; a plurality of substrates each having a first metallized side attached to the base region of the lead frame, a second metallized side opposite the first metallized side, and an insulating body that electrically isolates the first and second metallized sides from one another; at least one semiconductor die attached to the second metallized side of each substrate; and a mold compound encapsulating the semiconductor dies and part of the lead frame, wherein the semiconductor dies are electrically interconnected within the power module to form part of a power electronics circuit, wherein the base region of the lead frame is electrically isolated from the power electronics circuit by the insulating body of the substrates, wherein the leads of the lead frame protrude from one or more side faces of the mold compound and form terminals of the power module.

According to another embodiment of a power module, the power module comprises: a lead frame having a base region and a plurality of leads; an organic electrically insulative material applied to the base region of the lead frame; a metallization applied to the organic electrically insulative material; a plurality of semiconductor dies attached to the metallization; and a mold compound encapsulating the semiconductor dies and part of the lead frame, wherein the semiconductor dies are electrically interconnected within the power module to form part of a power electronics circuit, wherein the base region of the lead frame is electrically isolated from the power electronics circuit by the organic electrically insulative material, wherein the leads of the lead frame protrude from one or more side faces of the mold compound and form terminals of the power module.

According to an embodiment of a power module, the power module comprises: a lead frame having a base region and a plurality of leads; a plurality of power semiconductor dies supported by the base region of the lead frame; and a mold compound encapsulating the power semiconductor dies and part of the lead frame, wherein the power semiconductor dies are electrically interconnected within the power module to form part of a power electronics circuit, wherein the base region of the lead frame is electrically isolated from the power semiconductor dies, wherein the leads of the lead frame protrude from one or more side faces of the mold compound and form terminals of the power module.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1A illustrates a top perspective view of an embodiment of a molded power module.

FIG. 1B illustrates a cross-sectional view of the molded power module along the line labelled A-A′ in FIG. 1A.

FIGS. 2A through 2D illustrate top plan views of the molded power module shown in FIGS. 1A and 1B, during different stages of a manufacturing method.

FIG. 3 illustrates a top perspective view of a molded power module, according to another embodiment.

FIG. 4 illustrates a top perspective view of a molded power module, according to another embodiment.

FIG. 5 illustrates a top perspective view of a molded power module, according to another embodiment.

FIG. 6 illustrates a cross-sectional view of a molded power module, according to another embodiment.

FIG. 7 illustrates a top perspective view of a molded power module, according to another embodiment.

### DETAILED DESCRIPTION

The embodiments described herein provide a molded power module that includes a lead frame that has a base region for supporting substrates (die carriers) included in the module and leads which form terminals of the power module. The size of the substrates supported by the base region of the lead frame may be minimized since the substrates do not have to be used for current routing, thus lowering the overall cost of the module. Changes can be made to the module functionality (e.g., power output, pin configuration, etc.) without requiring a redesign of the substrates. The molded power module may be single-sided cooled or double-sided cooled. Instead of substrates (die carriers), an organic electrically insulative material may be applied to the base region of the lead frame with a metallization applied to the organic electrically insulative material. The semiconductor dies included in the module are attached to the metallization instead of substrates in this example. In either case (substrates or no substrates), the semiconductor dies included in the module are directly supported (no intermediary substrates) or indirectly supported (intermediary substrates included) by the base region of the lead frame.

Described next, with reference to the figures, are exemplary embodiments of the molded power module and methods of producing such a molded power module. Any of the molded power module embodiments described herein may be used interchangeably unless otherwise expressly stated.

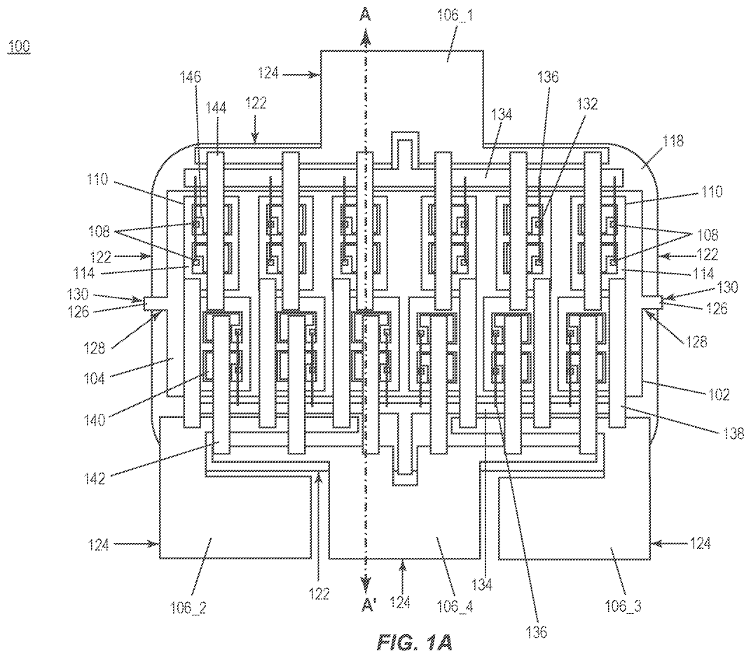

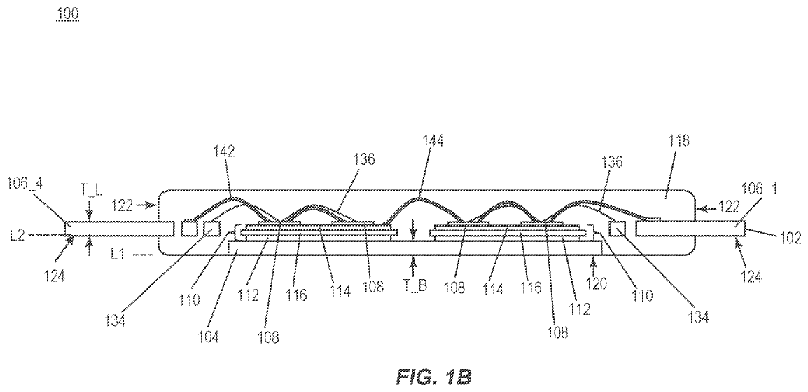

FIG. 1A illustrates a top perspective view of an embodiment of a molded power module 100. FIG. 1B illustrates a cross-sectional view of the molded power module 100 along the line labelled A-A′ in FIG. 1A. The molded power module 100 may form part of a power electronics circuit for use in various power applications such as in a DC/AC inverter, a DC/DC converter, an AC/DC converter, a DC/AC converter, an AC/AC converter, a multi-phase inverter, an H-bridge, etc.

The molded power module 100 includes a lead frame 102 having a base region 104 and leads 106. The lead frame 102 is a metallic frame (e.g., copper, copper-alloy, iron-nickel alloy, etc.) that is formed by stamping, punching, etching, etc. and that provides external electrical connection to the semiconductor dies (chips) 108 included in the molded power module 100 via the leads 106. The base region 104 of the lead frame 102 supports the semiconductor dies 108.

In FIGS. 1A and 1B, the base region 104 of the lead frame 102 indirectly supports the semiconductor dies 108 since each semiconductor die 108 is attached to a substrate (power electronics carrier) 110. More than one (1) substrate 110 may be included in the molded power module 100 and one or more semiconductor dies 108 may be attached to each substrate 110, e.g., as shown in FIGS. 1A and 1B.

Each substrate 110 has a first metallized side 112 attached to the base region 104 of the lead frame 102, a second metallized side 114 opposite the first metallized side 112, and an insulating body 116 such as a ceramic that electrically isolates the first and second metallized sides 112, 114 from one another. The base region 104 of the lead frame 102 ensures the substrates 110 are coplanar or nearly coplanar, reducing the overall tolerance of the molded power module 100 which is preferential for molding. A reduced module tolerance ensures less mold flash and lower stress on the substrates 110.

The substrates 110 may be, e.g., DCB (direct copper bonded) substrates, AMB (active metal brazed) substrates, IMS (insulated metal substrates), etc. All substrates 110 may be of the same type, or different types of substrates 110 may be used. For example, one or more of the substrates 110 may be a DCB substrate and one or more other ones of the substrates 110 may be an AMB substrate. This way, different die types (e.g., Si and SiC) may be supported by different types of substrates 110. In another example, all substrates 110 are DCB substrates, AMB substrates, or IMS substrates.

At least one semiconductor die 108 is attached to the second metallized side 114 of each substrate 110 included in the molded power module 100, e.g., by sintering, soldering, diffusion soldering, brazing, gluing, etc. Unlike conventional molded power modules, the second metallized side 114 of each substrate 110 may be unpatterned (i.e., not patterned) since the substrates 110 are not used for current routing. Conversely, the substrates included in conventional power modules are patterned to provide current routing. Accordingly, ‘islands’ of the patterned metallization are at different potentials (e.g., DC+, DC−, gate potential, etc.). In FIGS. 1A and 1B, the second metallized side 114 of each substrate 110 is unpatterned. Accordingly, the entire second metallized side 114 of each substrate 110 is at a single electric potential, which may be fixed (e.g., ground) or floating. Also, since the substrates 110 do not provide current routing, the substrate area may be reduced to a minimum which significantly reduces substrate cost. This enables high density for die attach and reduces the cost for batch processes such as sintering, soldering, etc. The substrates 110 may have the same or different thickness.

A mold compound (plastic) 118 encapsulates the semiconductor dies 108 and part of the lead frame 102. The mold compound 118 may include an organic resin such as epoxy resin, a filler such as non-melting inorganic materials, a pigment or colorant, a flame retardant, an adhesion promoter, ion traps, a stress reliever, etc.

As shown in FIG. 1B, the backside 120 of the base region 104 of the lead frame 102 opposite the substrates 110 may be exposed from the mold compound 118 to provided single-sided cooling of the molded power module 100. In one embodiment, the backside 120 of the base region 104 of the lead frame 102 is electroplated which protects the backside 120 from environmental damage and color change and allows for sinter/solder connections. Only the lower part of the mold compound 118 is shown in FIG. 1A, to provide an unobstructed view of the module components encapsulated by the mold compound 118.

The semiconductor dies 108 are electrically interconnected within the molded power module 100 to form part of a power electronics circuit such as an AC-to-DC rectifier, a DC-to-AC inverter, a DC-to-DC converter, and AC-to-AC converter, etc. In one embodiment, the semiconductor dies 108 are electrically interconnected within the molded power module 100 in a half bridge or full bridge configuration.

In FIGS. 1A and 1B, the base region 104 of the lead frame 102 is electrically isolated from the power electronics circuit by the insulating body 116 of the substrates 110. Accordingly, the base region 104 of the lead frame 102 is used for mechanical support only. The leads 106 of the lead frame 102 protrude from one or more side faces 122 of the mold compound 118 and form terminals of the molded power module 100. The terminals formed by the leads 106 of the lead frame 102 enable electrical connection of the power electronics circuit formed by the semiconductor dies 108 included in the molded power module 100 with another electrical device or interface, such as another module, a printed circuit board, etc.

The semiconductor dies 108 may be power Si or SiC power MOSFET (metal-oxide-semiconductor field-effect transistor) dies, HEMT (high-electron mobility transistor) dies, IGBT (insulated-gate bipolar transistor) dies, JFET (junction filed-effect transistor) dies, power diode dies, etc. As shown in FIGS. 1A and 1B, the semiconductor dies 108 are vertical power transistor dies. For a vertical power transistor die, the primary current flow path is between the front and back sides of the die. The drain terminal is typically disposed at the backside of the die, with the gate and source terminals (and optionally one or more sense terminals) at the frontside of the die. Additional types of semiconductor dies may be included in the molded power module 100, such as power diode dies, logic dies, controller dies, gate driver dies, etc. For the vertical die example shown in FIGS. 1A and 1B, the drain terminal of each semiconductor die 108 is connected to the second metallized side 114 of the corresponding substrate 110 with gate and source terminals (and optionally one or more sense terminals) at the opposite frontside of the dies 108.

Subsets of the semiconductor dies 108 may be attached to separate substrates 110, e.g., as shown in FIGS. 1A and 1B. For example, in the case of a half bridge power converter configuration, one or more semiconductor dies 108 may be attached to the same substrate 110 or more than one substrate 110 to form the high-side switch of the half bridge. Similarly, one or more semiconductor dies 108 may be attached to the same substrate 110 or more than one substrate 110 to form the low-side switch of the half bridge. The number of dies 108 and substrates 110 included in the molded power module 100 depends on several factors, including the type of power electronics circuit being implemented using the molded power module 100, the semiconductor die technology (Si and/or SiC and/or GaN, etc.), the substrate technology (DCB and/or AMB and/or IMS, etc.), etc.

For example, in FIG. 1A, the semiconductor dies 108 attached to the lower row (first group) of substrates 110 may be electrically coupled in parallel to form a low-side switch of a half bridge and the semiconductor dies 108 attached to the upper row (second group) of substrates 110 may be electrically coupled in parallel to form a high-side switch of the half bridge. In this example, a first lead 106_1 of the lead frame 102 forms a switch node terminal for the molded power module 100 which is electrically connected to the node between the high-side and low-side switch devices of the half bridge. Second and third leads 106_2, 106_3 of the lead frame 102 form a DC+ (high-side) power/phase terminal for the high-side switch device of the half bridge. A fourth lead 106_4 of the lead frame 102 forms a DC− (low-side) power/phase terminal for the low-side switch device of the half bridge. According to this embodiment, the entire second metallized side 114 of each substrate 100 in the lower row (first group) of the substrates 110 is at the switch node potential of the half bridge and the entire second metallized side 114 of each substrate 110 in the upper row (second group) of the substrates 110 is at the DC+ potential of the half bridge.

The lead frame 102 may be a single-gauge lead frame such that the base region 104 has the same thickness as the leads 106 (T_B=T_L in FIG. 1B). In another embodiment, the lead frame 102 is a dual-gauge lead frame such that the base region 104 is thinner or thicker than the leads 106 (T_B≠T_L in FIG. 1B). Separately or in combination, the base region 104 of the lead frame 102 may lie in a first horizontal plane L1 and a distal end 124 of the leads 106 of the lead frame 102 may terminate in a second horizontal plane L2 different than the first horizontal plane L1 (e.g., L1 is lower than L2 in FIG. 1B). Separately or in combination, the lead frame 102 may further include one or more tie bars 126 having a proximal end 128 that is connected to the base region 104 of the lead frame 102 and a severed distal end 130 that is accessible at a side face 122 of the mold compound 118. The tie bars 126 stabilize the base region 104 and leads 106 during the module manufacturing process and are severed after the molding process. The severed distal end 130 of a tie bar 126 may be tested to verify electrical isolation between the substrates 110 and the base region 104 of the lead frame, e.g., by probing the tie bar 126 or contacting a pin attached to the tie bar 126.

Internal electrical connections between the module leads 106 and the semiconductor dies 108 encased in the mold compound 118 may be provided by using one or more of wire bonds, wire ribbons, metal clips, a metal frame, etc. For example, in FIGS. 1A and 1B, electrical connections between gate pads 132 of the semiconductor dies 108 and respective patterned sections (islands) 134 of the lead frame 102 are provided by bond wires 136. In FIGS. 1A and 1B, electrical connections between the DC+ power/phase leads 106_2, 106_3 of the lead frame 102 and the second metallized side 114 of each substrate 110 in the upper row (second group) of the substrates 110 are provided by thicker bond wires or ribbons 138. In FIGS. 1A and 1B, electrical connections between the DC− power/phase lead 106_4 of the lead frame 102 and source pads 140 of the semiconductor dies 108 attached to each substrate 110 in the lower row (first group) of the substrates 110 are provided by thicker bond wires or ribbons 142. In FIGS. 1A and 1B, thicker bond wires or ribbons 144 provide electrical connections between the second metallized side 114 of each substrate 110 in the lower row (first group) of the substrates 110, source pads 146 of the semiconductor dies 108 attached to each substrate 110 in the upper row (second group) of the substrates 110, and the first lead 106_1 of the lead frame 102 to provide the half bridge switch node connection.

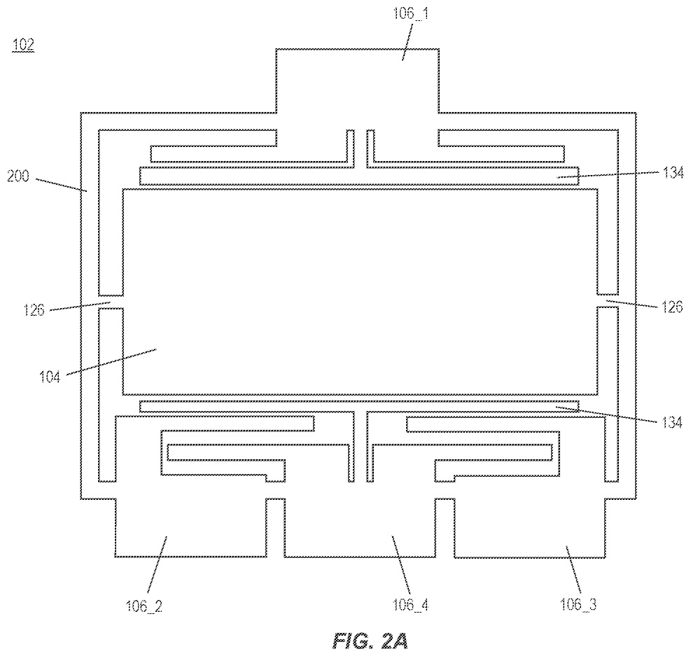

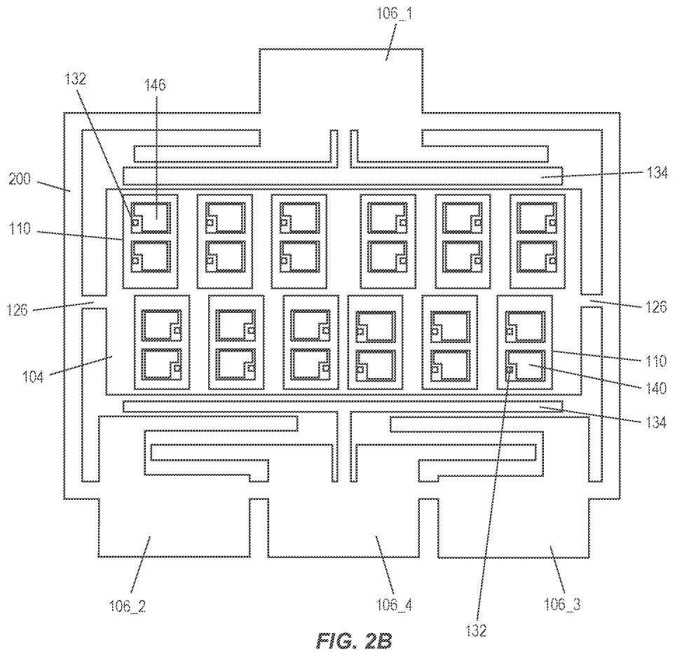

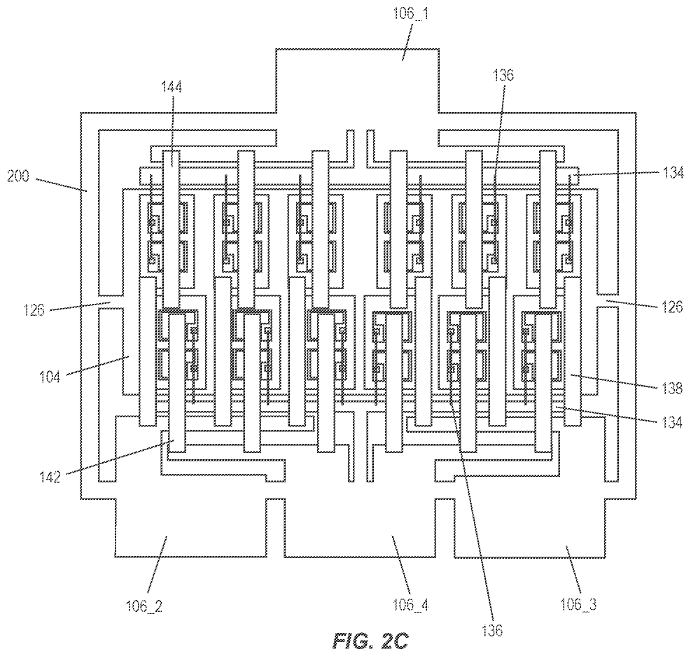

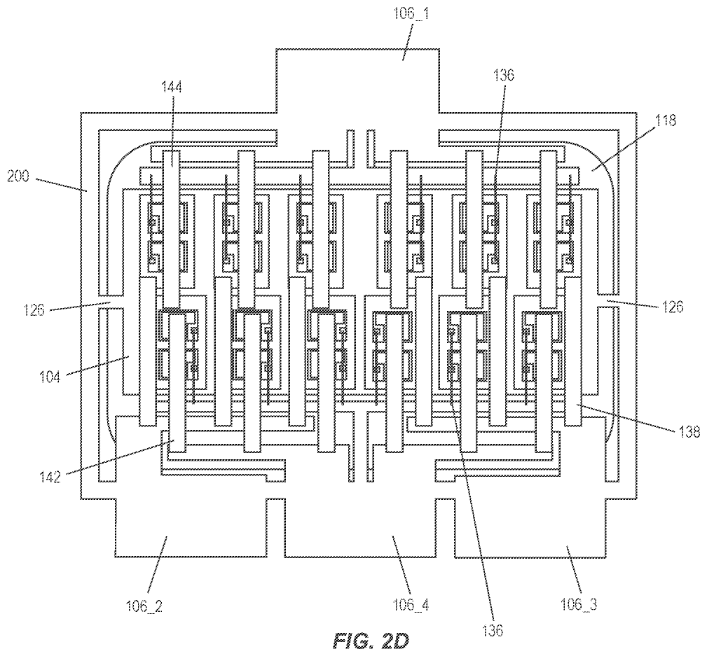

FIGS. 2A through 2D illustrate top plan views of the molded power module 100 shown in FIGS. 1A and 1B, during different stages of a manufacturing method.

FIG. 2A shows the lead frame 102 prior to substrate attachment. The lead frame 102 may be formed from a metallic sheet such as a sheet made of copper, a copper-alloy, an iron-nickel alloy, etc. The metallic sheet is patterned by stamping, punching, etching, etc. to define the features of the lead frame 102, including the base region 104 and the leads 106. The tie bars 126 anchor the base region 104 and the leads 106 to a peripheral structure 200 of the lead frame 104 that is handled during manufacturing of the molded power module 100.

FIG. 2B shows the substrates 110 attached to the base region 104 of the lead frame 102. The first metallized side 112 of each substrate 110 may be attached to the base region 104 of the lead frame 102 by sintering, soldering, diffusion soldering, brazing, gluing, etc.

FIG. 2C shows the electrical connections 136, 138, 142, 144 between the module leads 106 and the semiconductor dies 108. The electrical connections 136, 138, 142, 144 may be formed by wire bonding and ribbon bonding, for example. The base region 104 and the leads 106 remain anchored to the peripheral structure 200 of the lead frame 104 by the tie bars 126 while the electrical connections 136, 138, 142, 144 are formed.

FIG. 2D shows the semiconductor dies 108 and part of the lead frame 102 encapsulated in the mold compound 118. The mold compound 118 may be formed by injection molding, compression molding, film-assisted molding (FAM), reaction injection molding (RIM), resin transfer molding (RTM), blow molding, etc. Only the lower part of the mold compound 118 is shown in FIG. 2D, to provide an unobstructed view of the module components encapsulated by the mold compound 118.

The molded power module 100 is then subjected to a trim and form process during which each connection point between the peripheral structure 200 of the lead frame 102 and the tie bars 126, leads 106, and base region 104 of the lead frame 102 is severed outside the permitter of the mold compound 118. The exposed leads 106 and tie bars 126 may be plated before or after severing the peripheral structure 200.

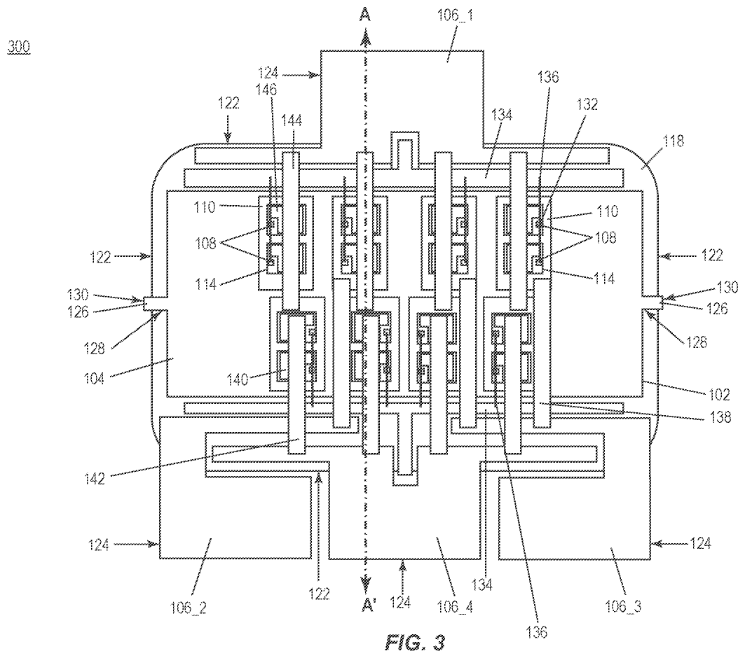

FIG. 3 illustrates a top perspective view of a molded power module 300, according to another embodiment. The molded power module 300 in FIG. 3 uses the same lead frame design as the molded power module 100 in FIGS. 1A and 1B. However, the molded power module 300 in FIG. 3 has fewer semiconductor dies 100 and fewer substrates 110 compared to the molded power module 100 in FIGS. 1A and 1B, e.g., in the case of a lower power module implementation. Despite this difference, the molded power modules 100, 300 have the same footprint. The excess part of the base region 104 of the lead frame 102 which arises in FIG. 3 due to the use of fewer semiconductor dies 100 and substrates 110 may be viewed as wasteful, but using the same lead frame design to support multiple module configurations (low power, mid power, high power, etc.) avoids a costly redesign for each different module configuration. Lead frames are relatively inexpensive compared to other module components, thus justifying the use of the same lead frame design across different module configurations.

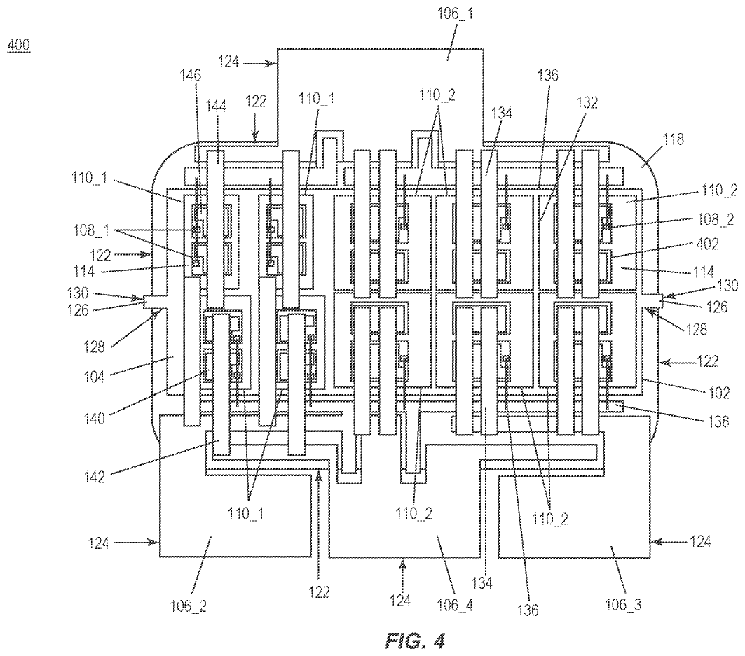

FIG. 4 illustrates a top perspective view of a molded power module 400, according to another embodiment. The substrates 110 in FIG. 4 include a first group of substrates 110_1 of a first substrate type and a second group of substrates 110_2 of a second substrate type different than the first substrate type. In one embodiment, a first type of semiconductor dies 108_1 are attached to the second metallized side 114 of the substrates 110_1 in the first group of substrates 110 and a second type of semiconductor dies 108_2 different than the first type of semiconductor dies 108_1 are attached to the second metallized side 114 of the substrates 110_2 in the second group of substrates 110. For example, the first substrate type 110_1 may be AMB, the second substrate type 110_2 may be DBC, the first type 108_1 of semiconductor dies 108 may be SiC dies, and the second type 108_2 of semiconductor dies 108 may be Si dies. In one embodiment, the SiC dies 108_1 are SiC MOSFET dies and the Si dies 108_2 are Si IGBT dies. SiC dies are more efficient at low load conditions and IGBT dies are more efficient at high load conditions. A power diode die 402 may be coupled to each Si IGBT die 108_2 to provide a freewheeling current path when the corresponding Si IGBT die 108_2 is off (blocking).

In another embodiment, the first group of substrates 110_1 and the second group of substrates 110_2 are the same type of substrate (DCB, AMB, IMS, etc.). According to this embodiment, the first type 108_1 of semiconductor dies 108 are attached to the second metallized side 114 of the first group of substrates 110_1 and the second (different) type 108_2 of semiconductor dies 108 are attached to the second metallized side 114 of the second (same type) group of substrates 110_2. Accordingly, different types 108_1, 108_2 of semiconductor dies 108 may be attached to the same type of substrate 110 or different types 110_1, 110_2 of substrates 110. In one embodiment, the first group 108_1 of the semiconductor dies 108 are power transistor dies such as power MOSFET dies, HEMT dies, IGBT dies, JFET dies, etc. and the second group 108_2 of the semiconductor dies 108 are logic dies and/or controller dies configured to drive and/or control the power transistor dies.

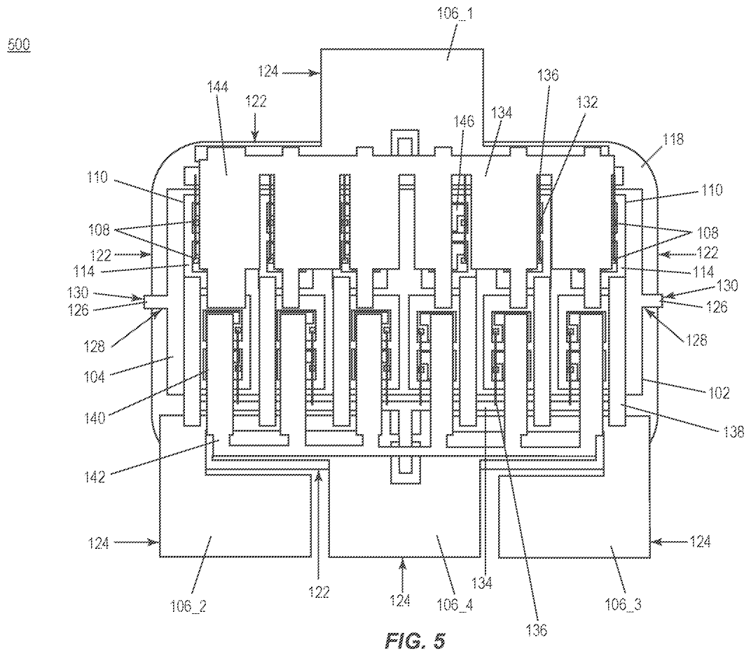

FIG. 5 illustrates a top perspective view of a molded power module 500, according to another embodiment. In FIG. 5, the internal electrical connections 136, 138, 142, 144 between the semiconductor dies 108, the substrates 110, and the respective patterned sections 106, 134 of the lead frame 102 are provided by a metallic frame 502 such as an additional lead frame or clip frame positioned above or below the first lead frame 102, e.g., by bumps or stamped features at the backside of the metallic frame 502, or by solder, electrically conductive adhesive, etc. The metallic frame 502 may be formed by stamping, punching, etching, etc. to define the interconnect features 138, 142, 144 of the metallic frame 502.

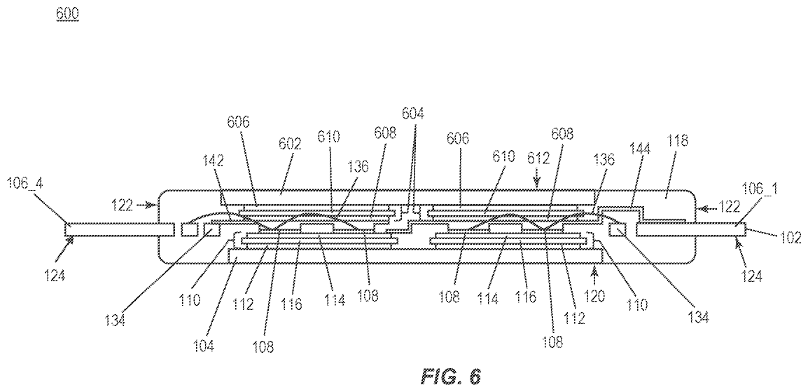

FIG. 6 illustrates a cross-sectional view of a molded power module 600, according to another embodiment. The molded power module 600 is similar to the molded power module 100 in FIGS. 1A and 1B but also includes an additional lead frame 602 above or below the first lead frame 102. The molded power module 600 in FIG. 6 also includes additional substrates 604 each having a first metallized 606 side attached to the additional lead frame 602, a second metallized side 608 opposite the first metallized side 606, and an insulating body 610 that electrically isolates the first and second metallized sides 606, 608 from one another. The mold compound 118 encapsulates part of the additional lead frame 602 and the additional lead frame 602 is electrically isolated from the power electronics circuit by the insulating body 610 of the additional substrates 604. In one embodiment, the backside 120 of the base region 104 of the first lead frame 102 that faces away from the first substrates 110 is uncovered by the mold compound 118 and the backside 612 of the additional lead frame 602 that faces away from the additional substrates 604 is also uncovered by the mold compound 118 such that the molded power module 600 in FIG. 6 has double-sided cooling. In one embodiment, the backside 120 of the base region 104 of the lead frame 102 and the backside 612 of the additional lead frame 602 are electroplated which protects both backsides 120, 612 from environmental damage and color change and allows for sinter/solder connections.

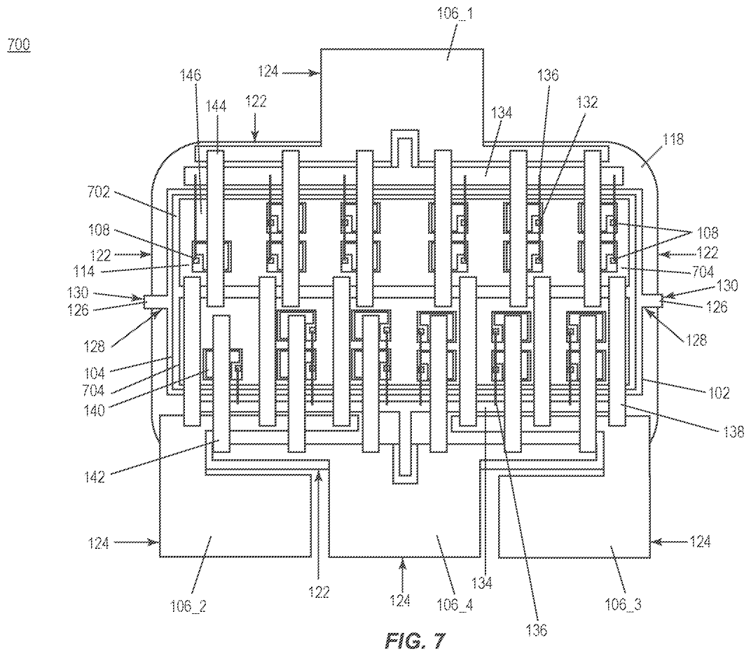

FIG. 7 illustrates a top perspective view of a molded power module 700, according to another embodiment. The molded power module 700 is similar to the molded power module 100 in FIGS. 1A and 1B. In FIG. 7, the base region 104 of the lead frame 102 directly supports the semiconductor dies 108 in that the semiconductor dies 108 are not attached to a substrate in FIG. 7. Instead, an organic electrically insulative material 702 is applied to the base region 104 of the lead frame 102, a metallization 704 is applied to the organic electrically insulative material 702, and the semiconductor dies 108 are attached to the metallization 704. The metallization 704 may be patterned as shown in FIG. 7 or a single contiguous layer, depending on the number and arrangement of the semiconductor dies 108.

In FIG. 7, the base region 104 of the lead frame 102 is electrically isolated from the power electronics circuit by the organic electrically insulative material 702. Accordingly, the base region 104 of the lead frame 102 is used for mechanical support only. In one embodiment, the organic electrically insulative material 702 is an epoxy-based layer such as an FR-4-based dielectric and the metallization 704 is a layer of copper laminated on the organic electrically insulative material 702 and having a thickness, e.g., of 35 μm to more than 200 μm. As previously explained herein, one or more of the semiconductor dies 108 may be power transistor dies and one or more other ones of the semiconductor dies 108 may be logic dies and/or controller dies configured to drive and/or control the power transistor dies.

Although the present disclosure is not so limited, the following numbered examples demonstrate one or more aspects of the disclosure.
Example 1. A power module, comprising: a lead frame having a base region and a plurality of leads; a plurality of substrates each having a first metallized side attached to the base region of the lead frame, a second metallized side opposite the first metallized side, and an insulating body that electrically isolates the first and second metallized sides from one another; at least one semiconductor die attached to the second metallized side of each substrate; and a mold compound encapsulating the semiconductor dies and part of the lead frame, wherein the semiconductor dies are electrically interconnected within the power module to form part of a power electronics circuit, wherein the base region of the lead frame is electrically isolated from the power electronics circuit by the insulating body of the substrates, wherein the leads of the lead frame protrude from one or more side faces of the mold compound and form terminals of the power module.
Example 2. The power module of example 1, wherein the second metallized side of each substrate is unpatterned.
Example 3. The power module of example 1 or 2, wherein the entire second metallized side of each substrate is at a single electric potential.
Example 4. The power module of any of examples 1 through 3, wherein the plurality of substrates comprises a first group of substrates of a first substrate type and a second group of substrates of a second substrate type different than the first substrate type.
Example 5. The power module of example 4, wherein a first type of semiconductor dies are attached to the second metallized side of the substrates in the first group of substrates, and wherein a second type of semiconductor dies different than the first type of semiconductor dies are attached to the second metallized side of the substrates in the second group of substrates.
Example 6. The power module of example 5, wherein the first substrate type is active metal brazed (AMB), wherein the second substrate type is direct bonded copper (DBC), wherein the first type of semiconductor dies are SiC dies, and wherein the second type of semiconductor dies are Si dies.
Example 7. The power module of example 6, wherein the SiC dies are SiC MOSFET dies, and wherein the Si dies are Si IGBT dies.
Example 8. The power module of any of examples 1 through 7, wherein a first type of semiconductor dies are attached to the second metallized side of the substrates in a first group of the substrates, and wherein a second type of semiconductor dies different than the first type of semiconductor dies are attached to the second metallized side of the substrates in a second group of the substrates.
Example 9. The power module of example 8, wherein the substrates in the first group of the substrates are a same type of substrate as the substrates in the second group of the substrates.
Example 10. The power module of example 8, wherein the substrates in the first group of the substrates are a different type of substrate as the substrates in the second group of the substrates.
Example 11. The power module of any of examples 1 through 10, wherein the semiconductor dies are electrically interconnected within the power module in a half bridge configuration, wherein the semiconductor dies attached to the second metallized side of the substrates in a first group of the substrates are electrically coupled in parallel to form a low-side switch of the half bridge, and wherein the semiconductor dies attached to the second metallized side of the substrates in a second group of the substrates are electrically coupled in parallel to form a high-side switch of the half bridge.
Example 12. The power module of example 11, wherein the entire second metallized side of each substrate in the first group of the substrates is at a switch node potential of the half bridge, and wherein the entire second metallized side of each substrate in the second group of the substrates is at a DC+ potential of the half bridge.
Example 13. The power module of any of examples 1 through 12, wherein the lead frame is a dual-gauge lead frame and the base region is thinner or thicker than the leads.
Example 14. The power module of any of examples 1 through 13, wherein the base region of the lead frame lies in a first horizontal plane, and wherein a distal end of the leads of the lead frame terminate in a second horizontal plane different than the first horizontal plane.
Example 15. The power module of any of examples 1 through 14, wherein a first group of the semiconductor dies are power transistor dies, and wherein a second group of the semiconductor dies are logic dies and/or controller dies configured to drive and/or control the power transistor dies.
Example 16. The power module of any of examples 1 through 15, wherein the lead frame further comprises a tie bar having a proximal end that is connected to the base region of the lead frame and a severed distal end that is accessible at a side face of the mold compound.
Example 17. The power module of any of examples 1 through 16, further comprising: an additional lead frame above or below the lead frame; and a plurality of additional substrates each having a first metallized side attached to the additional lead frame, a second metallized side opposite the first metallized side, and an insulating body that electrically isolates the first and second metallized sides from one another, wherein the mold compound encapsulates part of the additional lead frame, wherein the additional lead frame is electrically isolated from the power electronics circuit by the insulating body of the additional substrates.
Example 18. The power module of example 17, wherein a surface of the base region of the lead frame that faces away from the substrates is uncovered by the mold compound and a surface of the additional lead frame that faces away from the additional substrates is uncovered by the mold compound such that the power module has double-sided cooling.
Example 19. The power module of any of examples 1 through 18, wherein a side of the base region of the lead frame that faces away from the plurality of substrates is electroplated.
Example 20. A power module, comprising: a lead frame having a base region and a plurality of leads; an organic electrically insulative material applied to the base region of the lead frame; a metallization applied to the organic electrically insulative material; a plurality of semiconductor dies attached to the metallization; and a mold compound encapsulating the semiconductor dies and part of the lead frame, wherein the semiconductor dies are electrically interconnected within the power module to form part of a power electronics circuit, wherein the base region of the lead frame is electrically isolated from the power electronics circuit by the organic electrically insulative material, wherein the leads of the lead frame protrude from one or more side faces of the mold compound and form terminals of the power module.
Example 21. A power module, comprising: a lead frame having a base region and a plurality of leads; a plurality of power semiconductor dies supported by the base region of the lead frame; and a mold compound encapsulating the power semiconductor dies and part of the lead frame, wherein the power semiconductor dies are electrically interconnected within the power module to form part of a power electronics circuit, wherein the base region of the lead frame is electrically isolated from the power semiconductor dies, wherein the leads of the lead frame protrude from one or more side faces of the mold compound and form terminals of the power module.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power module, comprising:
a lead frame having a base region and a plurality of leads;
a plurality of substrates each having a first metallized side attached to the base region of the lead frame, a second metallized side opposite the first metallized side, and an insulating body that electrically isolates the first and second metallized sides from one another;
at least one semiconductor die attached to the second metallized side of each substrate; and
a mold compound encapsulating the semiconductor dies and part of the lead frame,
wherein the semiconductor dies are electrically interconnected within the power module to form part of a power electronics circuit,
wherein the base region of the lead frame is electrically isolated from the power electronics circuit by the insulating body of the substrates,
wherein the leads of the lead frame protrude from one or more side faces of the mold compound and form terminals of the power module.

2. The power module of claim 1, wherein the second metallized side of each substrate is unpatterned.

3. The power module of claim 1, wherein the entire second metallized side of each substrate is at a single electric potential.

4. The power module of claim 1, wherein the plurality of substrates comprises a first group of substrates of a first substrate type and a second group of substrates of a second substrate type different than the first substrate type.

5. The power module of claim 4, wherein a first type of semiconductor dies are attached to the second metallized side of the substrates in the first group of substrates, and wherein a second type of semiconductor dies different than the first type of semiconductor dies are attached to the second metallized side of the substrates in the second group of substrates.

6. The power module of claim 5, wherein the first substrate type is active metal brazed (AMB), wherein the second substrate type is direct bonded copper (DBC), wherein the first type of semiconductor dies are SiC dies, and wherein the second type of semiconductor dies are Si dies.

7. The power module of claim 1, wherein a side of the base region of the lead frame that faces away from the plurality of substrates is electroplated.

8. The power module of claim 1, wherein a first type of semiconductor dies are attached to the second metallized side of the substrates in a first group of the substrates, and wherein a second type of semiconductor dies different than the first type of semiconductor dies are attached to the second metallized side of the substrates in a second group of the substrates.

9. The power module of claim 8, wherein the substrates in the first group of the substrates are a same type of substrate as the substrates in the second group of the substrates.

10. The power module of claim 8, wherein the substrates in the first group of the substrates are a different type of substrate as the substrates in the second group of the substrates.

11. The power module of claim 1, wherein the semiconductor dies are electrically interconnected within the power module in a half bridge configuration, wherein the semiconductor dies attached to the second metallized side of the substrates in a first group of the substrates are electrically coupled in parallel to form a low-side switch of the half bridge, and wherein the semiconductor dies attached to the second metallized side of the substrates in a second group of the substrates are electrically coupled in parallel to form a high-side switch of the half bridge.

12. The power module of claim 11, wherein the entire second metallized side of each substrate in the first group of the substrates is at a switch node potential of the half bridge, and wherein the entire second metallized side of each substrate in the second group of the substrates is at a DC+ potential of the half bridge.

13. The power module of claim 1, wherein the lead frame is a dual-gauge lead frame and the base region is thinner or thicker than the leads.

14. The power module of claim 1, wherein the base region of the lead frame lies in a first horizontal plane, and wherein a distal end of the leads of the lead frame terminate in a second horizontal plane different than the first horizontal plane.

15. The power module of claim 1, wherein a first group of the semiconductor dies are power transistor dies, and wherein a second group of the semiconductor dies are logic dies and/or controller dies configured to drive and/or control the power transistor dies.

16. The power module of claim 1, wherein the lead frame further comprises a tie bar having a proximal end that is connected to the base region of the lead frame and a severed distal end that is accessible at a side face of the mold compound.

17. The power module of claim 1, further comprising:
an additional lead frame above or below the lead frame; and
a plurality of additional substrates each having a first metallized side attached to the additional lead frame, a second metallized side opposite the first metallized side, and an insulating body that electrically isolates the first and second metallized sides from one another,
wherein the mold compound encapsulates part of the additional lead frame,
wherein the additional lead frame is electrically isolated from the power electronics circuit by the insulating body of the additional substrates.

18. The power module of claim 17, wherein a surface of the base region of the lead frame that faces away from the substrates is uncovered by the mold compound and a surface of the additional lead frame that faces away from the additional substrates is uncovered by the mold compound such that the power module has double-sided cooling.

19. A power module, comprising:
a lead frame having a base region and a plurality of leads;
an organic electrically insulative material applied to the base region of the lead frame;
a metallization applied to the organic electrically insulative material;
a plurality of semiconductor dies attached to the metallization; and
a mold compound encapsulating the semiconductor dies and part of the lead frame,
wherein the semiconductor dies are electrically interconnected within the power module to form part of a power electronics circuit,
wherein the base region of the lead frame is electrically isolated from the power electronics circuit by the organic electrically insulative material,
wherein the leads of the lead frame protrude from one or more side faces of the mold compound and form terminals of the power module.

20. A power module, comprising:
a lead frame having a base region and a plurality of leads;
a plurality of power semiconductor dies supported by the base region of the lead frame; and
a mold compound encapsulating the power semiconductor dies and part of the lead frame,
wherein the power semiconductor dies are electrically interconnected within the power module to form part of a power electronics circuit,
wherein the base region of the lead frame is electrically isolated from the power semiconductor dies,
wherein the leads of the lead frame protrude from one or more side faces of the mold compound and form terminals of the power module.
